(19) United States
(12) Patent Application Publication
(10) Pub. No.: US 2012/0079176 A1
(43) Pub. Date: Mar. 29, 2012

(54) MEMORY DEVICE

(75) Inventors: Rixin Sun, Shenzhen (CN); Zhenhua Li, Shenzhen (CN)

(73) Assignee: BIWIN TECHNOLOGY LIMITED, Kowloon (CN)

(21) Appl. No.: 13/256,131

(22) PCT Filed: Jun. 25, 2010
(86) PCT No.: PCT/CN10/74540

§ 371 Date: Dec. 16, 2011

(51) Int. Cl. G06F 12/00; H01L 25/07

(52) U.S. Cl. 711/103; 257/777; 711/E12.008; 257/E25.018

(57) ABSTRACT

A multi-channel flash memory device comprising die-stacked flash memory dies. The flash memory device is compact due to the stacked dies arrangement while providing high speed performance due to its multiple data channel arrangement. A specific example is a flash memory comprising 4 stacked flash memory dies with 4 parallel data channels. This invention alleviates the bottle neck problems of know die-stacked flash memory devices.

### FIELD OF THE INVENTION

The present invention relates to memory devices, and more particularly to memory devices comprising a stack of flash memory members such as flash memory chips or dies. The present invention also relates to electronic apparatus comprising a stacked assembly of flash memory members.

### BACKGROUND OF THE INVENTION

Memory devices as electronic data storage are essential to the operation of many electronic apparatus, especially electronic apparatus controlled or controllable by a computer or a microprocessor. Such memory devices include USB memory sticks, solid state disks (SSD), mobile internet device (MID), etc. Among the various types of memory devices, flash memory is gaining increasing popularity due to its high performance-to-cost ratio, high data storage density, being solid state and being non-volatile. Whilst flash memory already represents a substantial improvement and advancement over predecessor memory devices, the ever increasing demand for ever higher data storage capacity means there is always a need to pack more flash memory into a single compact housing.

FIGS. 1 and 1A schematically show a prior art stacked flash memory assembly which utilizes a high-rise structure to increase data storage capacity. The memory assembly comprises a plurality of flash memory dies 102, 104, 106, 108 the data access terminals are bonded in a cascade manner. However, the performance of such a stacked flash memory assembly is not entirely satisfactory due to a data access bottle-neck at the bottom flash memory member in the stack. Furthermore, a defective data access terminal on one flash memory member may also cause malfunction of the corresponding data access terminals on other flash memory members in the stack.

### SUMMARY OF THE INVENTION

According to the present invention, there is provided a memory device comprising a stack of a plurality of flash memory members mounted on a substrate, wherein each flash memory member comprises a collection of data access terminals such as data input and output terminals, and each data access terminal of each of the plurality of flash memory member is individually bonded on the substrate and is individually accessible through contact terminals on the substrate. The memory device utilizes the advantages of the high-rise or die-stacking structure while alleviating the bottle neck effect due to individual or parallel data access to the individual members of the stacked assembly of flash memory members.

The provision of individually accessible data terminals on the substrate means that the memory device includes a die-stacked arrangement while facilitating multi-channel data communication. For example, for a memory device with 4 stacked flash memory dies of this invention, 4 data channels are available. Such a multi-channel capability is advantageous because it facilitates parallel data access and data transfer, thereby providing the public with a compact and yet fast memory device.

In one embodiment, at least the data input and output terminals of a flash memory member in the stack may be bonded to the substrate by bonding wires. All the bonding wires of the flash memory member may be on one lateral end or side of the flash memory member. Having all the bonding wires of a die on a single lateral end means space at the opposite lateral end could be reserved for wire bonding of an adjacent die in the stack. The bonding wires on an adjacent flash memory member in the stack may be bonded on a lateral side which is opposite the one lateral end or side. By stacking the flash memory members such that the boding wires are located at contact portions at directly opposite ends of the stack, more space is available for connecting the bonding wires to the substrate, especially when the bonding wires are naked conductors.

In one embodiment, the orientation of a flash memory member in the stack is shifted by about 90 degrees with respect to an immediately adjacent flash memory member in the stack. This provides even more space for bonding wire connection and makes a more efficient use of the space surrounding the stack. In such an embodiment, the stacking of the flash memory members is arranged such that the bonding wires of a flash memory member which is sandwiched between two immediately adjacent flash memory members are intermediate the bonded lateral sides of the adjacent flash memory members.

The bonding wires of a flash memory member in the stack may be bonded at one lateral end of the flash memory member, and the bonded lateral ends of the flash memory members in the stack may be distributed on a substantially or generally helical path. This further provides an even more optimal use of space surrounding the stack for bonding wire connection.

In general, the stack may be surrounded by bonding wires of the flash memory members, or surrounded by the bonding wires on at least on 4 lateral sides of the stack. It would be appreciated by persons skilled in the art that the space utilization of this arrangement is much more efficient and advantageous compared to prior art arrangements of FIGS. 1 and 1A.

Furthermore, the stack may be arranged such that the bonding wires on opposite lateral ends of the stack are symmetrically distributed about a centre plane of the stack. This provides a much more balanced stack structure compared to prior designs and permits more flash more members to stack in stability.

As an example, the data access terminals may be bonded to the substrate by bonding wires, and the bonding wires may be arranged such that bonding wires on a lower flash memory member on the stack are nested by bonding wires higher up in the stack. This nesting configuration, for example as depicted in FIGS. 2A and 3A, provides the flexibility of connecting more bonding wires on one lateral side of the stack or on one localized region on a substrate, thereby making die-stacking of flash memory members with individual I/O access on the substrate more possible or practical.

For example, the bonding wires may be arranged such that the flash memory member at the bottom of the stack is surrounded by an aggregate of bonding wires bonded to the stack. This arrangement provides a neat disposition of the bonding wires to mitigate crossing of bonding wires between bonding wires on the same lateral side of the stack.

In addition or in the alternative, the bonding wires may be distributed around the entire periphery of the stack. Likewise, this provides a more efficient use of space on the substrate surrounding the stack for efficient individual I/O connection.

In an embodiment, the bonded portion of a flash memory member of the stack overhangs a flash memory immediately underneath. This usefully provides additional headroom for running the bonding wires from a flash memory member to the substrate while optimizing the spatial efficiency of die-stacking.

As an example, a flash memory member in the stack may be oriented substantially orthogonal to an immediately adjacent flash memory member in the stack. The orthogonal arrangement provides efficient space utilization around the stack and on the substrate for individual I/O access.

As an example, the substrate may comprise a printed circuit board, including a multi-layered printed circuit board. A multi-layered PCB provides even more flexibility to permit even more access terminals of flash memory members to be individually accessible from the substrate.

Preferably, the stack may comprise at least 4 flash memory members each comprising a channel of data input and output terminals, and the 4 channels of the 4 flash memory members are individually accessible on the substrate. A memory device comprising such a stack of memory dies provides faster data I/O speed because 4 data channels are available compared to only a single channel of conventional die-stacked flash memory.

As an example, the stack may comprise a number N of flash memory members, where N=2ⁿ, n being an integer.

Generally, the collection of data input and output terminals collectively form a communication channel, and the contact terminals further comprise voltage and other non-data terminals.

The memory device may further comprise a data controller, wherein the data controller is arranged to access the data input and output terminals of the plurality of flash memory members in parallel.

The memory device may be part of a data storage apparatus comprising at least one memory device according to invention, wherein the data storage apparatus includes a USB memory stick, a solid state hard disc, or the like.

### BRIEF DESCRIPTION OF THE FIGURES

The invention will be explained by way of example and with reference to the accompany drawings, in which:

FIGS. 1 and 1A are respective side and perspective views of a prior art stacked flash memory assembly,

FIGS. 2 and 2A show respectively side and perspective schematic views of a memory device illustrating a first embodiment of the present invention,

FIGS. 3 and 3A show respectively side and perspective schematic views of a memory device illustrating a second embodiment of the present invention,

FIG. 4 is a schematic plan view showing a relationship of the wire bonding and the wire bonding terminals of the memory device of FIG. 2,

FIGS. 5 and 5A are respectively schematic block diagrams depicting a memory device of FIGS. 2, 3 and 8 and an exemplary application as a USB device,

FIGS. 6A and 6B are respectively schematic diagrams illustrating a distribution of contact terminals on a PCB of the device of FIG. 2, and an enlarged view of one of the contact regions,

FIG. 7 is a perspective schematic view of the device of FIG. 2 showing the I/O (input/output terminals) in more detail, and

FIGS. 8 and 8A are perspective schematic views depicting a memory assembly of a third embodiment of the present invention respective in assembled and part assembled form.

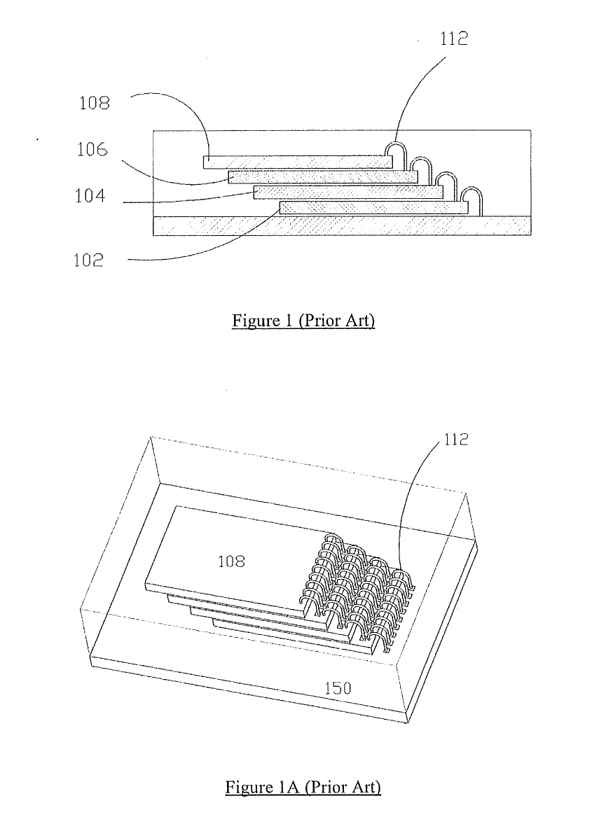

### DETAILED DESCRIPTION OF EXEMPLARY EMBODIMENTS

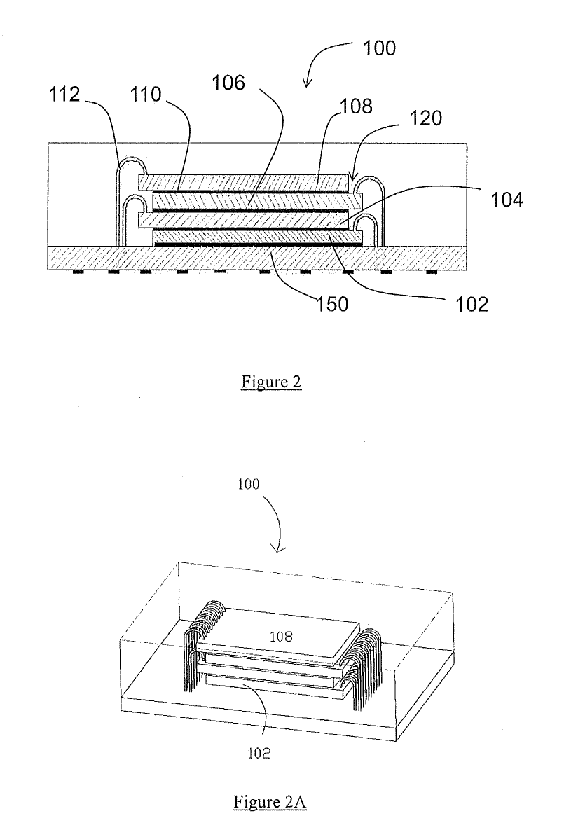

A flash memory assembly 100 of FIGS. 2, and 2A as an example of a memory device comprises a stack of 4 flash memory dies 102, 104, 106, & 108 each having a plurality of contact terminals 120 or contact ports for making external electrical connections. Each memory die is pre-fabricated with solid state and non-volatile memory cells and has a definitive storage capacity. Currently, flash memory dies are available in 1, 2, 4, or 8 gigabyte capacity. Of course, the storage capacity of an individual memory die or chip depends on the die size and the density is expected to increase with further improvements in die design and fabrication technology. The memory die used in the present example is a rectangular die having an exemplary dimension of 10.8 mm×13 mm. For example, by stacking four 1-gigabyte dies together, a single 4 gigabyte flash memory chip is formed. Likewise, a single 16 gigabyte flash memory is formed by stacking four 4-gigabyte flash memory dies.

The contact terminals 120 of each memory die 102-108 include data access terminals 130 such as data input and data output terminals, and other terminals 140 such as control terminals and power supply terminals. The data access terminals collectively define a multi-bit data communication channel for access to the die. The number of I/O terminals on each die is typically determined by the size of a byte. For example, if the byte size is 8-bit, each data communication channel would include 8 I/O terminals to facilitate 8 bit communication. Likewise, I/O terminals would collectively define a communication channel if the byte size is 16-bit. Because the unit of useable data is dependent on the byte size, the speed of a memory device is largely determined by the speed of the data communication channel since all data transfer to and from the die has to be through the communication channel.

The flash memory dies, as an example of flash memory members, are stacked in a high-rise manner using the “die-stacking” technique and adjacent flash memory dies, that is, dies above and below the die, are joined together by applying a thin film of insulating glue 110. The assembly comprising the stack of glued dies is then glued on a PCB 150, as an example of a substrate, by applying a thin film of insulating glue. The contact terminals on a memory die are connected to the contact terminals on the PCB by bonding wires 112.

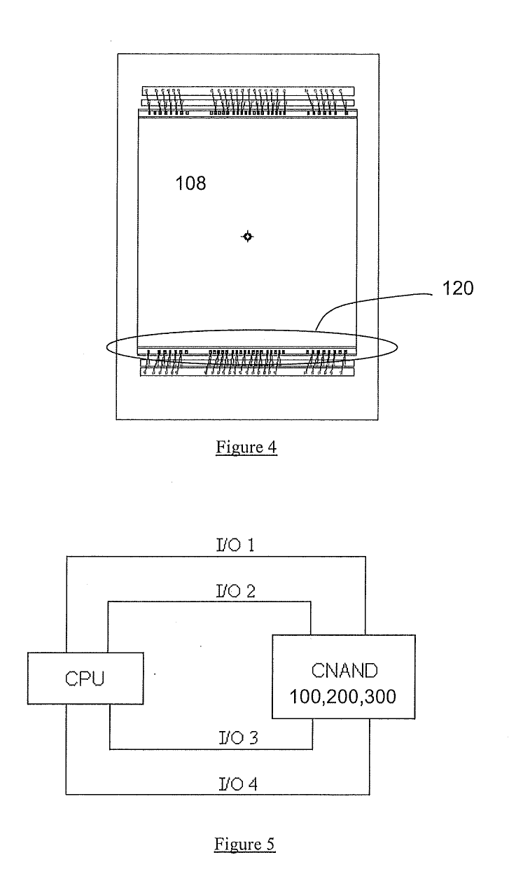

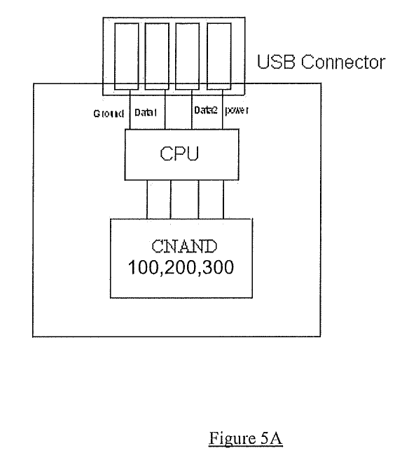

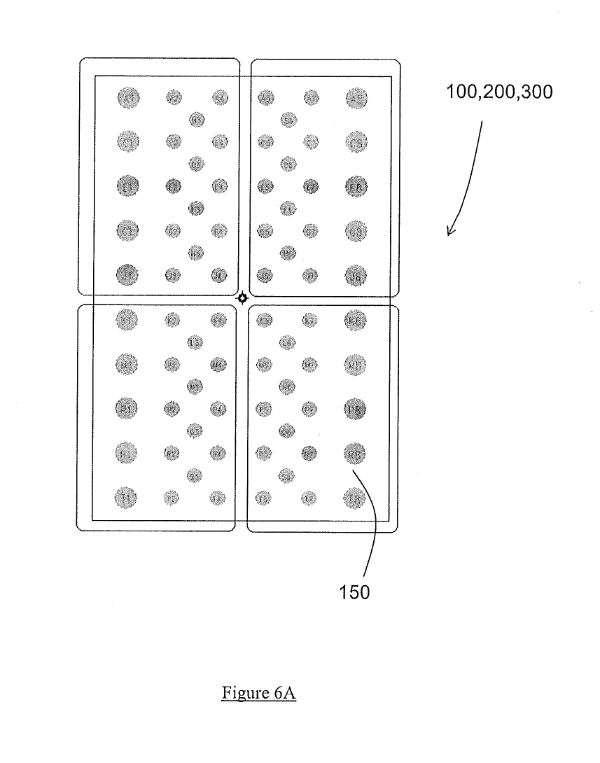

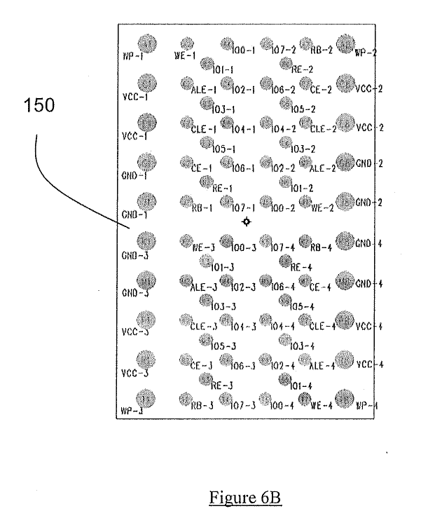

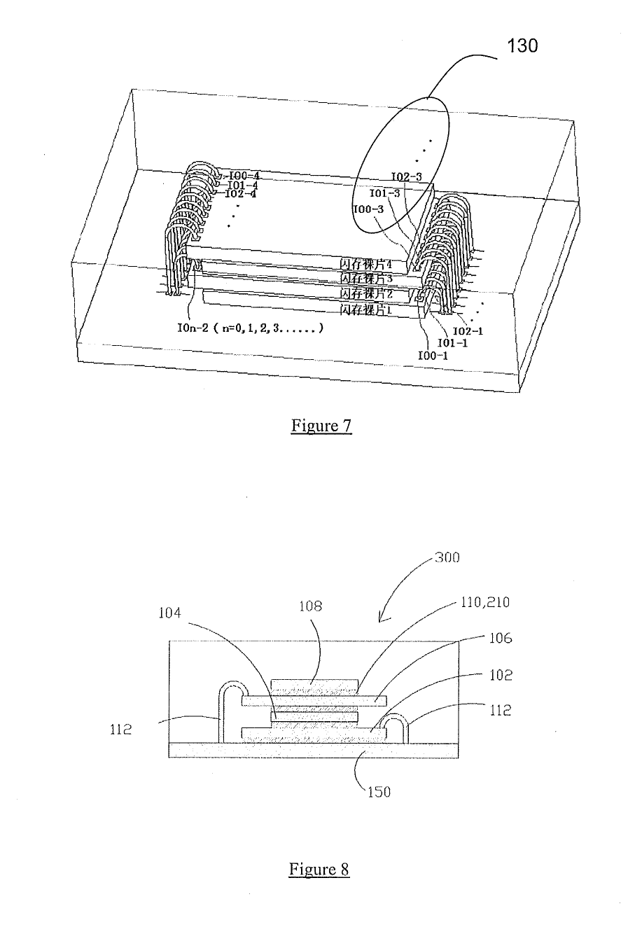

As shown more clearly in FIGS. 2, 2A and 4, all the contact terminals of a die are located on a contact portion which is located at one lateral end portion of the die. The stacking of dies is arranged such that the contact portion is exposed after stacking to permit external electrical connections to be made. The contact portion of a die protrudes from the stack and overhangs adjacent dies in the stack to provide a path and space for the bonding wires to negotiate from the die to the substrate. As shown more particularly in FIGS. 2 and 4, each one of the I/O terminals on a die is individually bonded on the substrate with bonding wires 112, such that each I/O terminal (and therefore data) on a die could be directly accessible without interfering with or being interfered by I/O terminals of other dies. This individual I/O connection arrangement facilitates parallel data access while using the die-stacking structure, as illustrated schematically in FIG. 5. As shown in FIGS. 6A and 6B, the PCB is arranged so that all the contact terminals of a die are located in a specific region on the PCB. This localized connection organization on the PCB facilitates easy identification and tracing of the individual terminals of an individual die in the stack.

As shown more particularly in FIGS. 2 and 2A, the dies are organized such that the contact portion of one die is on one lateral end, while that of an adjacent die is on the direct opposite lateral end. This zigzag stacking facilitates a more balanced and symmetrical stacking to facilitate a more stable structure and enables more dies to be stackable in a stack to further increase storage capacity. In addition, this stacking arrangement also provides a more space efficient arrangement for the bonding wire to negotiate when extending from the die to the PCB.

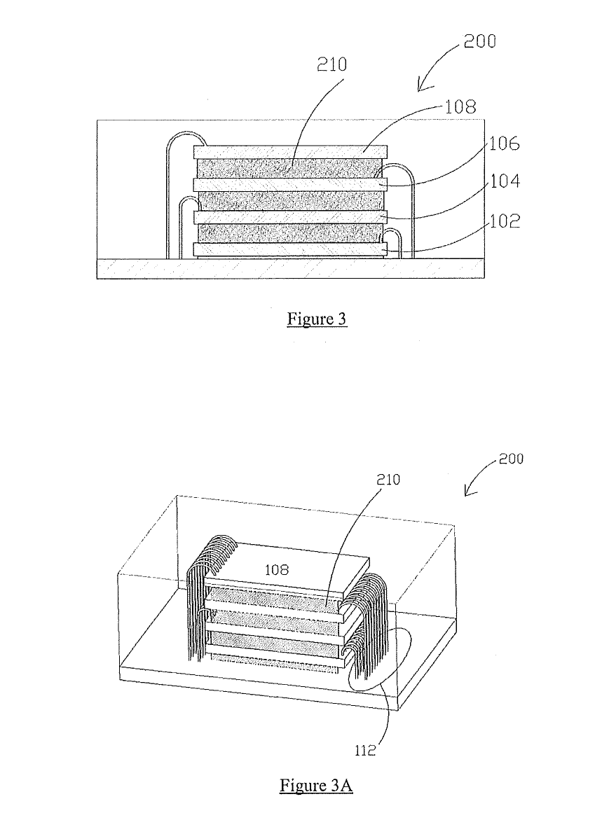

The stack assembly 200 of FIGS. 3 and 3A has a structure substantially identical to that of FIGS. 2 and 2A and same numerals are used to refer to same, common or equivalent parts. Instead of applying a thin film of insulating glue between the memory dies, the stack assembly 200 comprises includes a thick insulating glue layer 212 which also functions as a spacer between adjacent dies. The insulating spacer provides sufficient spacing so that bonding wires could extend upwardly initially without being obstructed by the die above and without the need of having a retreated die like that of the embodiment of FIG. 2. In particular, it will be noted that the lateral ends or the wire bonded ends of the dies of this assembly are substantially flush.

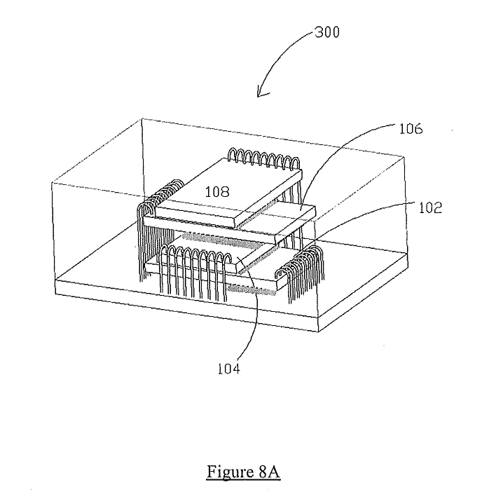

The stack assembly 300 of FIGS. 8 and 8A shows schematically a third embodiment of a flash memory device. The structure and connection of the flash memory dies and PCB are identical to that of FIG. 2, except that the orientation of the contact portion of a die is somewhat different. Likewise, same numerals are used to refer to same, common or equivalent parts. Specifically, the orientation of a die is orthogonal to that of an adjacent die, such that the orientation of the adjacent dies, especially the contact portions of the dies, are at 90 degree separation. In such a disposition, the contact terminals disposed on the PCB are configured to distribute about and surround the stack and more space on the PCB is available for wire bonding.

FIGS. 5 and 5A depicts an exemplary application of the memory device as a USB memory stick which is a convenient application of the present invention.

While the present invention has been explained with reference to the exemplary embodiments above, it should be appreciated by persons skilled in the art the embodiments are only for reference and should be regarded as restrictive on the scope of the invention. For example, while a rectangular die is used as an example, other shapes, such as square, circular or oval shaped could also be used as the shape of the die. Also, while the exemplary stack comprises 4 dies, it should be appreciated that more than 4 dies could be stacked together and a memory device could be assembled from more than one stack.

1. A memory device comprising a stack of a plurality of flash memory members mounted on a substrate, wherein each flash memory member comprises a collection of data access terminals such as data input and output terminals, and each data access terminal of each of the plurality of flash memory member is individually bonded on the substrate and is individually accessible through contact terminals on the substrate.

2. A memory device according to claim 1, wherein at least the data input and output terminals of a flash memory member in the stack are bonded to the substrate by bonding wires, and all the bonding wires of the flash memory member is on one lateral end or side of the flash memory member.

3. A memory device according to claim 2, wherein the bonding wires on an adjacent flash memory member in the stack is bonded on a lateral side which is opposite the one lateral end or side.

4. A memory device according to claim 2, wherein the orientation of a flash memory member in the stack is shifted by about 90 degrees with respect to an immediately adjacent flash memory member in the stack.

5. A memory device according to claim 4, wherein the stacking of the flash memory members is arranged such that the bonding wires of a flash memory member which is sandwiched between two immediately adjacent flash memory members are intermediate the bonded lateral sides of the adjacent flash memory members.

6. A memory device according to claim 1, wherein the bonding wires of a flash memory member in the stack are bonded at one lateral end of the flash memory member, and the bonded lateral ends of the flash memory members in the stack are on a substantially or generally helical path.

7. A memory device according to claim 1, wherein the stack is surrounded by bonding wires of the flash memory members, or surrounded by the bonding wires on at least on 4 lateral sides of the stack.

8. A memory device according to claim 1, wherein the stack is arranged such that the bonding wires on opposite lateral ends of the stack are symmetrically distributed about a centre plane of the stack.

9. A memory device according to claim 1, wherein the data access terminals are bonded to the substrate by bonding wires, and the bonding wires are arranged such that bonding wires on a lower flash memory member on the stack are nested by bonding wires higher up in the stack.

10. A memory device according to claim 9, wherein the bonding wires are arranged such that the flash memory member at the bottom of the stack is surrounded by an aggregate of bonding wires bonded to the stack.

11. A memory device according to claim 1, wherein the bonding wires are distributed around the entire periphery of the stack.

12. A memory device according to claim 1, wherein the bonded portion of a flash memory member of the stack overhangs a flash memory immediately underneath.

13. A memory device according to claim 1, wherein a flash memory member in the stack is oriented substantially orthogonal to an immediately adjacent flash memory member in the stack.

14. A memory device according to claim 1, wherein each flash memory member comprises a die of flash memory.

15. A memory device according to claim 1, wherein the substrate comprises a printed circuit board, including a multi-layered printed circuit board.

16. A memory device according to claim 1, wherein the stack comprises at least 4 flash memory members, each flash memory members comprising a channel of data input and output terminals; and the 4 channels of the 4 flash memory members are individually accessible on the substrate.

17. A memory device according to claim 1, wherein the stack comprise a number N of flash memory members, where N=2ⁿ, n being an integer.

18. A memory device according to claim 1, wherein the collection of data input and output terminals collectively form a communication channel, and the contact terminals further comprises voltage and other non-data terminals.

19. A memory device according to claim 1, further comprising a data controller, wherein the data controller is arranged to access the data input and output terminals of the plurality of flash memory members in parallel.

20. A data storage apparatus comprising at least one memory device according to claim 1, wherein the data storage apparatus includes a USB memory stick, a solid state hard disc, or the like.
